(19) United States
(12) Patent Application Publication
(10) Pub. No.: US 2013/0012008 A1
(43) Pub. Date: Jan. 10, 2013

(54) METHOD OF PRODUCING SOI WAFER

(76) Inventors: Bong-Gyun Ko, Tokyo (JP); Tetsuya Nakai, Tokyo (JP)

(21) Appl. No.: 13/637,166

(22) PCT Filed: Mar. 23, 2011
(86) PCT No.: PCT/JP11/01694

§ 371 Date: Sep. 25, 2012

(30) Foreign Application Priority Data
Mar. 26, 2010 (JP) 2010-072161

(51) Int. Cl. H01L 21/265

(52) U.S. Cl. 438/517; 257/E21.334

(57) ABSTRACT

The present invention provides a method of producing a high quality SOI wafer having a thin BOX layer with high productivity. In the method of producing an SOI wafer by performing heat treatment on a silicon wafer after implanting oxygen ions into silicon wafer, first ion implantation is performed on the silicon wafer to a high dose of 2×10¹⁷ ions/cm² to 3×10¹⁷ ions/cm², and then second ion implantation is performed to a low dose of 5×10¹⁴ ions/cm² to 1×10¹⁶ ions/cm². Subsequently, heat treatment is performed in a high oxygen concentration atmosphere at an oxygen partial pressure ratio of 10% to 80%, and then heat treatment is performed in a low oxygen atmosphere at an oxygen partial pressure ratio of less than 10%. After that, heat treatment is performed in a chlorine-containing gas atmosphere by adjusting the oxygen atmosphere to the chlorine-containing gas atmosphere by flowing argon through a chlorine-containing solution.

### TECHNICAL FIELD

The present invention relates to a method of producing an SOI wafer, and in particular relates to a method of producing a high quality SOI wafer having a thin BOX layer by SIMOX method.

### RELATED ART

In recent years, wafers having an SOI (Silicon on Insulator) structure (hereinafter referred to as “SOI wafer”) are attracting attention toward further improvement of device performance. An SOI wafer has a structure in which a silicon single crystal layer (SOI layer) is formed on a buried oxide layer (BOX layer), so that parasitic capacitance of the SOI wafer is significantly small as compared with devices manufactured on a bulk substrate, the production process is simple, and the shrinkage of devices is easy. Therefore, the SOI wafer holds promise as wafers for next-generation high performance VLSI having excellent performances such as high speed device operation, low power consumption, high breakdown voltage, radiation hardness, and the like.

A bonding method and a SIMOX (Separation by Implanted OXygen) method are mainly used as the method of producing the SOI wafer.

A bonding method is a method of producing an SOI wafer by bonding together a silicon support substrate having an oxidized surface and an active substrate for producing a device, performing heat treatment at a high temperature of approximately 1200° C., and bonding the oxide film of the support substrate and silicon of the active substrate.

On the other hand, a SIMOX method is a method of producing an SOI wafer by implanting oxygen ions to a predetermined depth into a silicon wafer using an ion implanter, and then forming a BOX layer by high temperature heat treatment to recover the crystallinity of an SOI layer formed on the BOX layer.

Currently commercially available SOI wafers produced by a SIMOX method (hereinafter referred to as “SIMOX wafers”), are mainly produced by the MLD (Modified Low Dose) method, in which oxygen ions are implanted into a silicon wafer in two stages. That is, the first oxygen ion implantation is performed after heating a silicon wafer to 200° C. or more, and the subsequent second oxygen ion implantation is performed after cooling the silicon wafer to about room temperature (for example, see Patent Document 1).

On this occasion, since the first oxygen ion implantation is performed on the heated silicon wafer, an oxygen rich layer is formed inside the silicon wafer while the silicon surface remains single crystallinity. Further, in the second oxygen ion implantation, an amorphous layer is formed above the oxygen rich layer, and a defect layer is formed in and above the amorphous layer. After that, an oxidation process called ITOX (InTernal OXidation) is performed at a high temperature in the atmosphere of a mixed gas comprising of oxygen and argon to efficiently increase the thickness of the BOX layer and to improve quality of the BOX layer, thus forming an SOI structure.

Recently, in manufacturing devices using SOI wafers, thin BOX layers, for example, having a thickness of 50 μm or less have come to be required to control voltage from the substrate side, for heat dissipation to the substrate, and the like. However, in an existing SIMOX method, oxygen ions of approximately 2.0×10¹⁷ to 4.0×10¹⁷ ions/cm² are introduced (supplied) to a silicon wafer even only during ion implantation, so that an oxide film having a thickness estimated to be approximately 45 nm to 90 nm is formed inside the silicon wafer. The BOX layer becomes thicker in a subsequent ITOX process; therefore, a BOX layer having a thickness of 100 nm or more is formed eventually. Therefore, it is physically difficult to produce a SIMOX wafer having a thin BOX layer of, for example 50 nm or less, by an existing SIMOX process, and establishment of a technique for thinning the BOX layer is expected.

Patent Document 2 discloses a technique of reducing divots formed on a surface of an SOI wafer by flowing a chlorine-containing gas in ITOX, and describes that the thickness of a BOX layer is reduced by increasing flow rate of the chlorine-containing gas.

Further, Patent Document 3 discloses a technique of thinning a BOX layer to a desired thickness by heat treatment in a chlorine-containing gas atmosphere when the thickness of the BOX layer in the produced SOI wafer is larger than the desired thickness.

### PRIOR ART DOCUMENTS

### Patent Documents

Patent Document 1: U.S. Pat. No. 5,930,643
Patent Document 2: U.S. Pat. No. 6,495,429
Patent Document 3: JP2007-180416 A

### DISCLOSURE OF THE INVENTION

### Problems to be Solved by the Invention

However, in the method disclosed in Patent Document 2, although divots on a surface of an SOI wafer can be prevented, degradation in the quality of the BOX layer, such as deterioration in the breakdown voltage still remains a problem.

On the other hand, in the method disclosed in Patent Document 3, heat treatment must be performed again after producing an SOI wafer to thin the BOX layer, which makes the production process complex and reduces productivity. Moreover, during heat treatment in the chlorine-containing gas atmosphere, the surface of an SOI wafer contacts the chlorine-containing gas without or with a relatively thin protective film such as an oxide film. Therefore, the surface roughness or the like is caused and the quality of the SOI layer would be degraded. Further, since the SOI layer is oxidized and thinned during the heat treatment in the chlorine-containing gas atmosphere, the method can be used only for wafers having an SOI layer which is rather thick, for example 200 nm or more, considering the thinning of the BOX layer by the heat treatment. For preparing such a wafer by SIMOX process, an SOI layer should be formed with reduced oxygen concentration, which would however degrade the quality of the BOX layer to deteriorate the breakdown voltage characteristics. Therefore, also considering the energy limit of current oxygen implanters (approximately 250 keV at a maximum), it is difficult to form a high quality SOI layer having a thickness of, for example 200 μm or more, while maintaining high breakdown voltage characteristics of the BOX layer.

An object of the present invention is therefore to provide a method of producing a high quality SOI wafer having a thin BOX layer of 50 μl or less with high productivity by SIMOX process.

### Means for Solving the Problem

The inventors of the present application made various studies on the breakdown voltage capability of a BOX layer obtained by the method disclosed in Patent Document 2 and found that the breakdown voltage capability is influenced by the chlorine-containing gas introduced in the ITOX process. That is, they found that applying the chlorine-containing gas atmosphere in a suitable stage after an ITOX process is effective in producing a high quality SOI wafer with a thinned BOX layer and further leads to high productivity. Thus, the present invention was made.

Accordingly, a method of producing an SOI wafer according to the present invention by performing heat treatment on a silicon wafer after oxygen ions are implanted into the silicon wafer is characterized in that the heat treatment on the silicon wafer is performed first in a high-oxygen atmosphere, and then in a chlorine-containing gas atmosphere containing chlorine by adjusting the high-oxygen atmosphere to the chlorine-containing gas atmosphere. Thus, a high quality SOI wafer can be produced with high productivity.

Further, the adjustment of the high-oxygen atmosphere to the chlorine-containing gas atmosphere is preferably performed by passing argon gas through a solution of a chlorine-containing gas at a flow rate of 30 cc/min or more. Thus, an SOI wafer having a BOX layer with a thickness of 50 μm or less can be produced.

Furthermore, the chlorine-containing gas is preferably one selected from the group consisting of trans-1, 2-dichloroethylene, trichloroethylene, and hydrogen chloride.

Further, the oxygen ion implantation is preferably performed in two stages: a first stage performed at an acceleration energy of 100 keV to 230 keV to a dose of 2×10¹⁷ ions/cm² to 3×10¹⁷ ions/cm²; and a second stage performed at an acceleration energy of 100 keV to 230 keV to a dose of 5×10¹⁴ ions/cm² to 1×10¹⁶ ions/cm². This allows forming a thick BOX layer efficiently at a low dose.

Preferably, heat treatment is performed in a low oxygen atmosphere at an oxygen partial pressure ratio of less than 10% immediately before the heat treatment in a chlorine-containing gas atmosphere. This allows producing an SOI wafer having high crystallinity and good flatness.

### Effect of the Invention

According to the present invention, a high quality SOI wafer having a thin BOX layer of 50 μm or less can be produced with high productivity by SIMOX process.

### BRIEF DESCRIPTION OF THE DRAWINGS

FIG. 1(a) is a flowchart of a method of producing SOI according to the present invention, and FIGS. 1(b) to 1(e) are diagrams each showing a structure of a silicon wafer in a step of the method of producing SOI.

FIG. 2(a) is a diagram showing a heat treatment process in a method of producing SOI in accordance with the present invention; FIG. 2(b): an invention of Patent Document 2; and FIGS. 2(c-1) and 2(c-2): inventions of Patent Document 3.

FIG. 3 is a plot showing the relationship between the thickness of the BOX layer and the dielectric breakdown voltage.

FIG. 4 is a plot showing the relationship between the DCE flow rate and the breakdown field.

### BEST MODE FOR CARRYING OUT THE INVENTION

A method of producing an SOI wafer in accordance with the present invention will now be described.

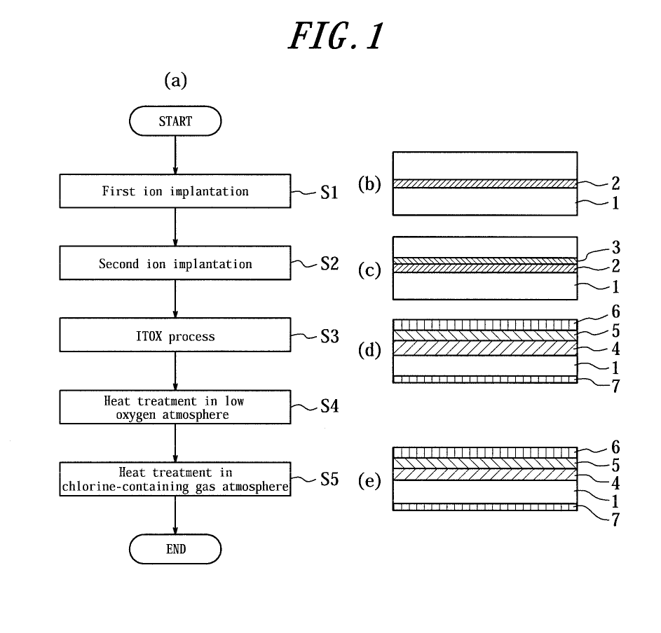

FIG. 1(a) is a flowchart of a method of producing an SOI wafer according to the present invention. FIGS. 1(b) to 1(e) show structures of a silicon wafer in respective production steps. First, oxygen ion implantation is performed on a silicon wafer 1. In the present invention, the above-mentioned MLD method is employed as an ion implantation method, and oxygen ions are implanted in two stages. Specifically, in step S1, the first ion implantation is performed at an acceleration energy of 100 keV to 230 keV, to an oxygen ion dose of 2×10¹⁷ ions/cm² to 3×10¹⁷ ions/cm², and at a substrate temperature of 200° C. to 500° C. As a result, an oxygen rich layer 2 is formed in the silicon wafer 1 as shown in FIG. 1(b). In this first ion implantation process, the silicon wafer 1 is heated to 200° C. or higher. Therefore, the wafer surface remains single crystallinity.

The acceleration energy of the first ion implantation is limited to 100 keV to 230 keV for the following reasons. When the acceleration energy is lower than 100 keV, the damage peak is located in a shallow position and the surface region damaged by the first implantation becomes amorphous by the second implantation and the crystallinity of the surface region would not be recovered. On the other hand, when the acceleration energy is higher than 230 keV, a BOX layer is formed in a significantly deep region and a thick SOI layer remains thereon; therefore, the thinning rate of the BOX layer is reduced, which results in reduced thinning efficiency. Thus, an additional process for thinning the thick SOI layer is required. Further, the dose of oxygen ions is set within the range of 2×10¹⁷ ions/cm² to 3×10¹⁷ ions/cm² for the following reasons. When the dose is less than 2×10¹⁷ ions/cm², the BOX layer would be discontinuous. Meanwhile, when the dose is more than 3×10¹⁷ ions/cm², many defects occur so that the breakdown voltage characteristics of the BOX layer are deteriorated. Furthermore, the substrate temperature is set within the range of 200° C. to 500° C. for the following reasons. When the substrate temperature is lower than 200° C., serious implantation damage is caused and the crystallinity would not be completely recovered; moreover, the BOX layer formed is thick, which is disadvantageous for thinning the BOX layer. Meanwhile, when the substrate temperature is higher than 500° C., the temperature would be increased by the implantation, but the heat resistance of components such as an implant holder is restricted.

Next, in step S2, the second oxygen ion implantation is performed at an acceleration energy of 100 keV to 230 keV, to an oxygen ion dose of 5×10¹⁴ ions/cm² to 1×10¹⁶ ions/cm², and at a substrate temperature of 10° C. to 150° C.

The second oxygen ion implantation is performed at a relatively low temperature; accordingly, an amorphous layer 3 is formed on the oxygen rich layer 2 as shown in FIG. 1(c).

The acceleration energy of the second ion implantation is limited to 100 keV to 230 keV for the following reasons. When the acceleration energy is lower than 100 keV, the damage peak is located in a shallow position and the surface region damaged by the first implantation becomes amorphous by the second implantation and the crystallinity of the surface region would not be recovered. When the acceleration energy is higher than 230 keV, a BOX layer is formed in a significantly deep region and a thick SOI layer remains thereon; therefore, the thinning rate of the BOX layer is reduced, which results in reduced thinning efficiency. Thus, an additional process for thinning the thick SOI layer is required. The dose of oxygen ions is set to the range of 5×10¹⁴ ions/cm² to 1×10¹⁶ ions/cm² because the dose range is suitable for forming an amorphous layer having an appropriate thickness at constant depth. Moreover, the substrate temperature is set within the range of 10° C. to 150° C. for the following reasons. When the substrate temperature is lower than 10° C., amorphization is promoted to expand to form a thick BOX layer, which is disadvantageous for thinning the BOX layer. Meanwhile, when the substrate temperature is higher than 150° C., amorphization hardly occurs, which makes it difficult to form a high quality BOX layer.

Next, heat treatment is performed on the silicon wafer 1 into which ions have been implanted. In the heat treatment, the silicon wafer 1 into which ions have been implanted is introduced into an annealing furnace and the temperature of the furnace is increased. Further, an ITOX process which oxidizes the silicon wafer 1 in a high-oxygen atmosphere is performed to form a thick BOX layer and an SOI layer, and heat treatment is then performed in a low oxygen atmosphere to improve the crystallinity of these layers. First, in step S3, a silicon wafer into which ions have been implanted is loaded into an annealing furnace and heated to perform ITOX process at an oxygen partial pressure ratio of 10% to 80%, at a temperature inside the furnace of 1100° C. to 1400° C., and for a processing time of 5 to 15 hours. Thus, an oxygen rich layer 2 is formed and a BOX layer 4 is formed from the amorphous layer 3; an SOI layer 5 and an oxide film 6 are formed thereover. Further, an oxide film 7 is formed on the rear surface of the silicon wafer 1, as shown in FIG. 1(d).

In the ITOX process, the temperature inside the furnace is limited to 1100° C. to 1400° C. for the following reasons. When the temperature is lower than 1100° C., a diffusion of oxygen into the substrate hardly occurs, which leads to little effect of the ITOX process. Meanwhile, when the temperature is higher than 1400° C., surface oxidation progresses rapidly, which makes oxygen hardly diffuse into the substrate; further, the high temperature increases the probability of forming defects such as slip. The oxygen partial pressure ratio is set within the range of 10% to 80% due to the following reasons. When the ratio is less than 10%, the amount of oxygen is small, which makes the diffusion of oxygen into the substrate hardly occur. Meanwhile, a ratio more than 80% is disadvantageous in terms of film thickness control because the flatness is deteriorated due to higher oxidation rate, and the SOI layer is eliminated due to rapid progress of surface oxidation, for example. Further, the processing time is limited to 5 to 15 hours for the following reasons. The quality, defect density, and breakdown voltage of a BOX layer are time-dependent, and a processing time less than 5 hours results in high defect density and low breakdown voltage capability of the BOX layer. On the other hand, when the processing time is more than 15 hours, the oxidation time is too long, and both surface oxidation and internal oxidation progress excessively. Thus, an SOI layer is eliminated and the BOX layer becomes too thick.

Subsequently, in step S4, heat treatment is performed in a low oxygen atmosphere at an oxygen partial pressure ratio of less than 10%, at a temperature inside the furnace of 1100° C. to 1400° C., and for a processing time of 15 hours or less, thereby improving the crystallinity and the flatness of the surface of the SOI layer.

The temperature inside the furnace in the heat treatment in a low oxygen atmosphere is limited to 1100° C. to 1400° C. for the following reasons. When the temperature is lower than 1100° C., atomic rearrangement in the surface region becomes less likely to occur because of the low temperature, which is less effective for improving the flatness. Meanwhile, when the temperature is higher than 1400° C., defects such as slip become likely to occur. Further, the oxygen partial pressure ratio is limited to less than 10% because an oxygen partial pressure ratio of 10% or more would cause the diffusion of oxygen and defects such as oxygen precipitate are formed in the SOI layer. The processing time is limited to 15 hours or less because slip due to thermal stress would occur when the processing time is more than 15 hours.

Then, in step S5, after the ITOX process and the heat treatment in a low oxygen atmosphere, chlorine-containing gas is introduced into the atmosphere to adjust the oxygen atmosphere to a chlorine-containing gas atmosphere, and a heat treatment process is performed. Thus, the BOX layer 4 is thinned as shown in FIG. 1(e). This is because chlorine promotes oxidation at the silicon wafer surface, and as the amount of oxygen supplied only from the surface is insufficient, oxygen comes to be supplied from the BOX layer. In the foregoing process, after the heat treatment in the low oxygen atmosphere, heat treatment in a chlorine-containing gas atmosphere is performed without removing the silicon wafer out of the annealing furnace. This is an important process in producing a high quality SOI wafer having a thin BOX layer as described above. This heat treatment is performed at a treatment temperature of 1100° C. to 1400° C. for a processing time of 1 to 15 hours.

Here, the treatment temperature is limited to the range of 1100° C. to 1400° C. for the following reasons. When the temperature is lower than 1100° C., an oxidation rate of the SOI layer is low and the processing time is excessively long. Meanwhile, when the temperature is higher than 1400° C., the oxidation rate of the SOI layer is high, which makes it difficult to control the film thickness; and slip occurs due to thermal stress. Preferably, the treatment temperature is 1250° C. to 1380° C. The processing time is limited to 1 to 15 hours for the following reasons. When the processing time is less than one hour, considering the thinning rate of the BOX layer, the process is substantially the same as the thinning achieved by heat treatment at high temperature under a low oxygen condition. Further, in this case, the short processing time would have a little thinning effect. Meanwhile, when the processing time is more than 15 hours, considering normal thinning rates, the BOX layer would be completely eliminated and slip would occur due to thermal stress.

The chlorine-containing gas used in the above heat treatment can be selected from the group consisting of trans-1, 2-dichloroethylene (DCE), trichloroethylene (TCE), and hydrogen chloride. DCE is preferably used since it is stable and easy to handle. Further, when a solution of chlorine-containing gas (hereinafter referred to as “chlorine-containing solution”), for example, a DCE solution is used for introducing chlorine into an annealing furnace, argon gas is bubbled through a vessel containing the DCE solution, and the amount of chlorine to be introduced is controlled by the flow rate of the argon gas that is a carrier gas. When a gas such as hydrogen chloride is used, the amount of chlorine is controlled by the mixing ratio of the gas to the above carrier gas.

The flow rate of the argon gas passed through the chlorine-containing solution is set to 10 cc/min to 300 cc/min, and preferably to 30 cc/min to 150 cc/min, so that the partial pressure of the argon gas is set to 0.1% to 3%. The flow rate of argon gas is limited as described above for the following reasons. When the flow rate is less than 10 cc/min, the low thinning rate of the BOX layer results in long heat processing time. When the flow rate is more than 300 cc/min, the oxidation rate of the SOI layer is too high to control the film thickness of the SOI layer.

Moreover, the amount of oxygen contained in the chlorine-containing gas atmosphere is set so that the partial pressure is 1% to 50%, preferably 5% to 20%. This is because an oxygen concentration of less than 1% results in long processing time due to the low oxidation rate, and an oxygen concentration of more than 20% makes it difficult to control the film thickness of the SOI layer due to the too high oxidation rate.

According to the present invention, the flow rate of argon gas passed through the chlorine-containing solution is set to 30 cc/min or more, so that an SOI wafer having a BOX layer of 50 μm or less can be obtained.

After the heat treatment in the low oxygen atmosphere, the temperature inside the furnace is lowered and the silicon substrate is unloaded. Then, a surface oxide film(s) 6 (and 7) of the silicon wafer processed by the above-mentioned series of steps is removed by etching or the like, thereby obtaining an SOI wafer.

Thus, a high quality SOI wafer having a thin BOX layer of 50 μm or less can be produced with high productivity.

### EXAMPLE

Examples of the present invention will be described in detail below.

### Invention Examples 1 to 4

First, oxygen ions were implanted into a silicon wafer having a diameter of 300 mm using an ion implanter. The MLD method was used as a method for implanting oxygen ions. The wafer was heated to approximately 350° C. and the dose was set to approximately 2.5×10¹⁷ ions/cm² to perform a first oxygen ion implantation, and then, after the temperature of the wafer was lowered to room temperature, a second oxygen ion implantation was performed to a dose of approximately 3×10¹⁵ ions/cm². The degree of vacuum in the chamber was approximately 1.5×10⁻⁴ Torr.

Next, the silicon wafer into which ions had been implanted was loaded into an annealing furnace in a nitrogen atmosphere at 600° C., and the temperature inside the furnace was increased at a heating rate of approximately 10° C./min to 1350° C. Subsequently, ITOX process was performed in an argon atmosphere containing oxygen at a partial pressure ratio of 30% at 1350° C. for approximately 7 hours. After that, heat treatment was performed in an argon atmosphere containing oxygen at a partial pressure ratio of 4% at 1350° C. for approximately 7 hours in low oxygen atmosphere.

After the above heat treatment in the low oxygen atmosphere, heat treatment was performed on the silicon wafer in a DCE atmosphere at a treatment temperature of 1350° C., for a processing time of 10 hours, at a flow rate of argon passed through a DCE solution (hereinafter referred to as “DCE flow rate”) of 10 cc/min (Invention Example 1), 20 cc/min (Invention Example 2), 30 cc/min (Invention Example 3), or 47 cc/min (Invention Example 4), at an oxygen gas flow rate of 1.6 L/min, and at a flow rate of argon gas as a carrier gas of 12.2 L/min.

Subsequently, the temperature was lowered at a cooling rate of approximately −10° C./min to 600° C., and the silicon wafer was unloaded. Finally, the surface oxide film was removed by etching using a hydrogen fluoride (HF) solution to obtain an SOI wafer. The result of evaluating the quality of the obtained SOI wafers is shown in Table 1. The thickness of the BOX layer, corresponding to the item “film thickness” in Table 1 is the thickness of the BOX layer, measured after producing the SOI wafer. Meanwhile, the thickness of the BOX layer corresponding to the item “BOX layer Breakdown voltage characteristics” is a thickness after removing the SOI layer by etching to evaluate the breakdown voltage characteristics, which has been slightly reduced by etching.

It was found that the thickness of the BOX layers in Invention Examples 1 to 4 is inversely proportional to the DCE flow rate, and this indicates that the thickness of the BOX layers can be controlled with high controllability. Further, it was found that when the DCE flow rate is 30 cc/min or more, the thickness of the BOX layer becomes 50 μm or less.

TABLE 1

| | | | Comparative | Comparative | Comparative | Invention | Invention | Invention | Invention | Invention |
|---|---|---|---|---|---|---|---|---|---|---|
| | | | Example 1 | Example 2 | Example 3 | Example 1 | Example 2 | Example 3 | Example 4 | Example 5 |
| | | | DCE flow | DCE flow | DCE flow | DCE flow | DCE flow | DCE flow | DCE flow | DCE flow |
| | | | rate = | rate = | rate = | rate = | rate = | rate = | rate = | rate = |
| | | | 0 cc/min | 5 cc/min | 150 cc/min | 10 cc/min | 20 cc/min | 30 cc/min | 47 cc/min | 30 cc/min |
| Film | Surface oxide | Av. (Å) | 6301 | 6496 | 8507 | 6608 | 6717 | 6937 | 7136 | 8244.7 |
| thickness | film | | | | | | | | | |
| | SOI layer | Av. (Å) | 1698 | 1623 | 345 | 1488 | 1472 | 1437 | 1421 | 1030.7 |
| | | Range (Å) | 23 | 22 | 24 | 20 | 24 | 25 | 23 | 23 |
| | BOX layer | Av. (Å) | 1713 | 1524 | 554 | 717 | 614 | 496 | 326 | 110.1 |
| | | Range (Å) | 31 | 25 | 27 | 25 | 20 | 18 | 15 | 18 |
| Crystal | HF defect | Number | 0 | 1 | 31 | 1 | 0 | 6 | 0 | 31 |
| defect | | Evaluation area | 157 | 157 | 157 | 157 | 157 | 157 | 157 | 157 |
| | | (cm²) | | | | | | | | |
| | | Density | 0 | 0.01 | 0.2 | 0.01 | 0 | 0.04 | 0 | 0.2 |
| | | (1/cm²) | | | | | | | | |
| SOI layer | 10 μm × 10 μm | Rms (Å) | 3.1 | 2.8 | 21 | 2.17 | 2.72 | 2.71 | 2.58 | 2.29 |
| Surface | | Rmax (Å) | 30.9 | 29.2 | 223.1 | 20.24 | 21.99 | 22.79 | 20.01 | 17.41 |
| micro- | 30 μm × 30 μm | Rms (Å) | 4.2 | 3.3 | 32.1 | 3.38 | 3.26 | 3.34 | 3.4 | 4.09 |
| flatness | | Rmax (Å) | 39.3 | 28.4 | 298.8 | 28.05 | 28.01 | 25.01 | 36.57 | 36.89 |
| BOX layer | BOX layer | Å | 1670 | 1500 | 530 | 673 | 576 | 468 | 308 | 93 |
| Breakdown | thickness | | | | | | | | | |
| voltage | Shorts Density | 1/cm² | 0 | 0.127 | 123 | 0.127 | 0 | 0.127 | 0.467 | 0.127 |
| character- | Leakage | nA | 0.0223 | 0.056 | 0.7 | 0.0244 | 0.0102 | 0.019 | 0.0204 | 0.0021 |
| istics | current | | | | | | | | | |
| | Breakdown | V | 90 | 73 | 10.6 | 55.1 | 47.6 | 39.2 | 26.7 | 9.2 |
| | voltage | | | | | | | | | |
| | Breakdown | MV/cm | 5.4 | 4.9 | 2 | 8.19 | 8.26 | 8.38 | 8.67 | 9.89 |
| | field | | | | | | | | | |

### Invention Example 5

Production conditions of an SOI wafer having an extremely thin BOX layer of about 10 nm, which is thinner than those in Invention Examples 1 to 4 were examined. Oxygen ion implantation, ITOX process, and low oxygen concentration annealing were performed under the same conditions as those in Invention Examples 1 to 4. In addition, heat treatment in a chlorine-containing gas atmosphere was performed under conditions of: treatment temperature: 1350° C., flow rate of argon gas passed through a DCE solution: 30 cc/min, and oxygen gas flow rate: 1.6 L/min that are the same as those in Invention Example 1. However, the heat treatment was performed for a processing time of 11 hours and 30 minutes and at a flow rate of argon gas as a carrier gas of 5.6 L/min. As a result, the BOX layer had a thickness of approximately 10 nm. Thus, it is considered that the thickness of the BOX layer was reduced significantly more than in Invention Examples 1 to 4 because the flow rate of the argon gas was reduced from 12.2 L/min to 5.6 L/min to reduce the total gas flow rate and the partial pressure of DCE flowing through the annealing furnace was increased, which results in a further thinning of the BOX layer. The obtained evaluation result is shown in Table 1.

### Comparative Examples 1 and 2

An SOI wafer having a thin BOX layer was produced by the method disclosed in Patent Document 2, that is, a method in which chlorine-containing gas is introduced in ITOX process. First, oxygen ions were implanted into a silicon wafer having a diameter of 300 mm using an ion implanter. The MLD method was used for implanting oxygen ions. After the wafer was heated to approximately 350° C., a first oxygen ion implantation was performed to a dose of approximately 2.5×10¹⁷ ions/cm². After the temperature of the wafer was lowered to room temperature, a second oxygen ion implantation was performed to a dose of approximately 3×10¹⁵ ions/cm². The degree of vacuum in the chamber was 1.5×10⁻⁴ Torr.

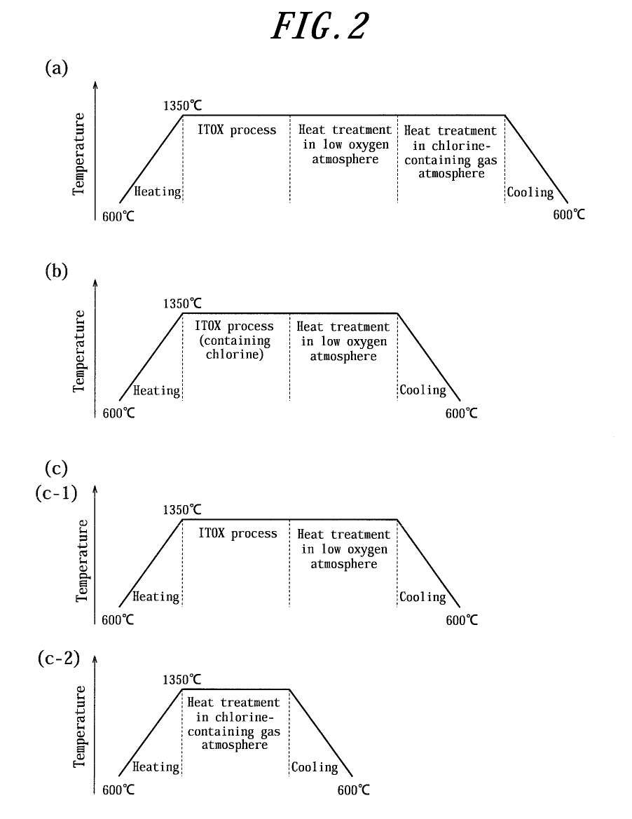

Next, heat treatment shown in FIG. 2(b) was performed. Specifically, after a silicon wafer into which oxygen ions had been implanted was loaded in a nitrogen atmosphere at 600° C. and the temperature inside the furnace was increased at a heating rate of approximately 10° C./min to 1350° C., ITOX process was then performed under conditions of: oxygen partial pressure ratio: 30%, DCE flow rate: 0 (Comparative Example 1) or 5 cc/min (Comparative Example 2), treatment temperature: 1350° C., and processing time: approximately 5 hours.

After that, heat treatment was performed in an argon atmosphere containing oxygen at a partial pressure ratio of 4% in low oxygen atmosphere at 1300° C. for approximately 5 hours. The obtained evaluation result is shown in Table 1.

### Comparative Example 3

An SOI wafer having a thin BOX layer was produced by the method disclosed in Patent Document 3, that is a method in which heat treatment is performed in a chlorine-containing gas atmosphere after once producing an SOI wafer. First, oxygen ions were implanted into a silicon wafer having a diameter of 300 mm using an ion implanter. The MLD method was used for implanting oxygen ions. After the wafer was heated to approximately 350° C., a first oxygen ion implantation was performed to a dose of approximately 2.5×10¹⁷ ions/cm². After the temperature of the wafer was lowered to room temperature, a second oxygen ion implantation was performed to a dose of approximately 3×10¹⁵ ions/cm². The degree of vacuum in the chamber is 1.5×10⁻⁴ Torr.

Next, heat treatment shown in FIG. 2(c-1) was performed. Specifically, after the silicon wafer into which ions had been implanted was loaded in nitrogen atmosphere at 600° C. and the temperature inside the furnace was increased at a heating rate of approximately 10° C./min to 1350° C., ITOX process was then performed in an argon gas atmosphere containing oxygen at a partial pressure ratio of 30% at 1350° C. for approximately 10 hours. After that, heat treatment was performed in a low oxygen atmosphere in an argon gas atmosphere containing oxygen at a partial pressure ratio of 4% at 1350° C. for approximately 5 hours; and subsequently the temperature was lowered at a cooling rate of approximately −10° C./min to 600° C. Then, the silicon wafer was unloaded. The surface oxide film had a film thickness of 590 nm, the SOI layer: 210 nm, and the BOX layer: 80 nm. Next, the surface oxide film was removed by etching using a HF solution to obtain an SOI wafer. Subsequently, the BOX layer was thinned by heat treatment shown in FIG. 2(c-2). The conditions of loading, unloading, heating, and cooling were the same as those in the heat treatment in FIG. 2(c-1), and heat treatment at 1350° C. was performed at a DCE flow rate of 150 cc/min, an oxygen flow rate of 2 L/min, and a flow rate of argon gas as a carrier gas of 10 L/min for 4 hours. After the heat treatment, the surface oxide film had a thickness of 276 nm, the SOI layer: 53 nm, and the BOX layer: 12 nm. The result of evaluating the quality of the obtained SOI wafers is shown in Table 1.

### (Quality Evaluation Result)

Now, the result of evaluating the quality of the obtained SOI wafers is examined.

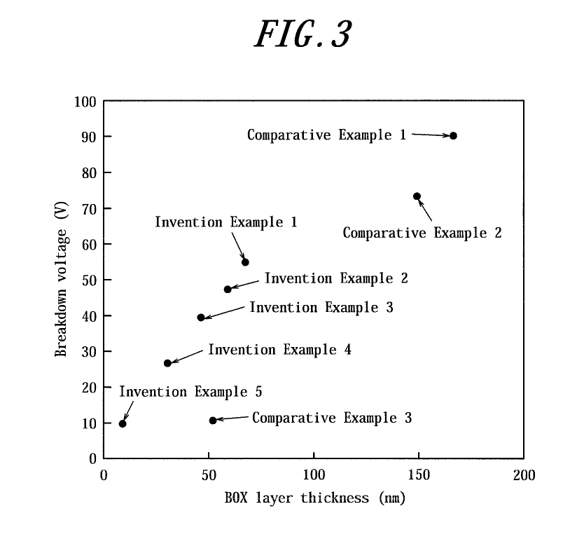

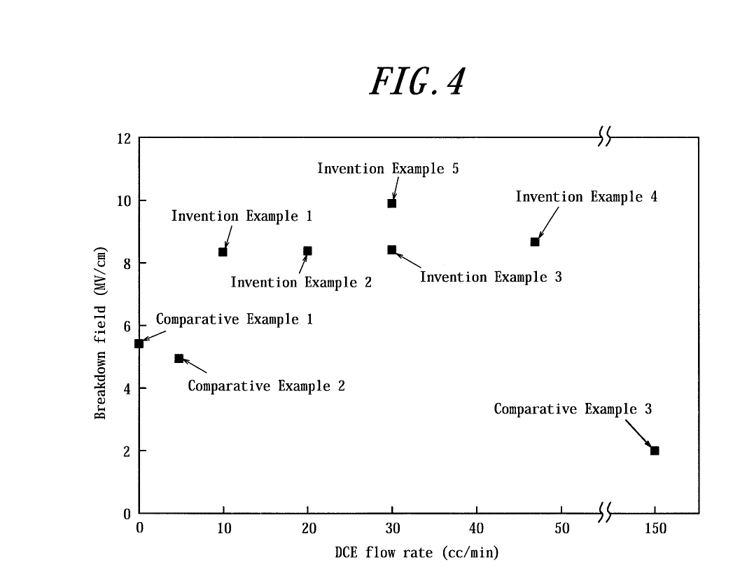

First, the breakdown voltage characteristics of the BOX layer are examined. FIG. 3 shows the relationship between the thickness and the breakdown voltage of the BOX layers in Invention Examples 1 to 5 and Comparative Examples 1 and 2. As seen from the plot, thicker BOX layers generally have higher dielectric breakdown voltage. With respect to the relationship between DCE flow rate and breakdown field shown in FIG. 4, the breakdown field of the SOI wafers of Invention Examples 1 to 5, obtained by methods according to the present invention is approximately 8.2 MV/cm or more. Meanwhile, when the production method of Patent Document 2, that is a method in which DCE is applied to the ITOX process, the breakdown field is about 5 MV/cm. Further, the breakdown field increases as the DCE flow rate increases in Invention Examples 1 to 5; on the other hand, the breakdown field decreases instead in Comparative Examples 1 and 2. Note that the breakdown field of an SOI wafer obtained by the method of Patent Document 3, that is, a method in which a BOX layer is thinned after producing an SOI wafer in Comparative Example 3, is approximately 2 MV/cm, which is only about ¼ as compared to Invention Examples 1 and 2. Thus, in the method of producing an SOI wafer according to the present invention, heat treatment in a chlorine-containing gas atmosphere allows a BOX layer to be thinned and the BOX layer to be formed to have high breakdown voltage characteristics.

Now, the quality of SOI layers is evaluated. As shown in Table 1, the surface micro-flatness of the SOI layer evaluated using an AFM (Atomic Force Microscope) for Invention Examples 1 to 7 and Comparative Example 3 indicates that the rms of an area of 10 μm×10 μm in Invention Examples 1 to 7 is approximately 2.2 a.u. to 2.7 a.u.; meanwhile, the rms is approximately 21 a.u. in Comparative Example 3, that is almost ten times greater. Thus, the flatness of the surface of an SOI layer is significantly improved by a method of producing an SOI wafer according to the present invention.

### INDUSTRIAL APPLICABILITY

The present invention can provide a high quality SOI wafer having a BOX layer of 50 μm or less; therefore, it is advantageous for devices required to be thin.

### EXPLANATION OF REFERENCE NUMERALS

1: Silicon wafer
2: Oxygen rich layer
3: Amorphous layer
4: BOX layer
5: SOI layer
6, 7: Surface oxide film

1. A method of producing an SOI wafer by performing heat treatment on a silicon wafer after implanting oxygen ions into the silicon wafer; wherein the heat treatment on the silicon wafer is performed first in a high-oxygen atmosphere, and then in a chlorine-containing gas atmosphere containing chlorine by adjusting the high-oxygen atmosphere to the chlorine-containing gas atmosphere.

2. The method of producing an SOI wafer according to claim 1, wherein the adjustment of the high-oxygen atmosphere to the chlorine-containing gas atmosphere is performed by passing argon gas through a solution of a chlorine-containing gas at a flow rate of 30 cc/min or more.

3. The method of producing an SOI wafer according to claim 2, wherein the chlorine-containing gas is one selected from the group consisting of trans-1, 2-dichloroethylene, trichloroethylene, and hydrogen chloride.

4. (canceled)

5. (canceled)

6. The method of producing an SOI wafer according to claim 1, wherein the oxygen ion implantation is performed in two stages: a first stage performed at an acceleration energy of 100 keV to 230 keV to a dose of 2×10¹⁷ ions/cm² to 3×10¹⁷ ions/cm²; and a second stage performed at an acceleration energy of 100 keV to 230 keV to a dose of 5×10¹⁴ ions/cm² to 1×10¹⁶ ions/cm².

7. The method of producing an SOI wafer according to claim 2, wherein the oxygen ion implantation is performed in two stages: a first stage performed at an acceleration energy of 100 keV to 230 keV to a dose of 2×10¹⁷ ions/cm² to 3×10¹⁷ ions/cm²; and a second stage performed at an acceleration energy of 100 keV to 230 keV to a dose of 5×10¹⁴ ions/cm² to 1×10¹⁶ ions/cm².

8. The method of producing an SOI wafer according to claim 3, wherein the oxygen ion implantation is performed in two stages: a first stage performed at an acceleration energy of 100 keV to 230 keV to a dose of 2×10¹⁷ ions/cm² to 3×10¹⁷ ions/cm²; and a second stage performed at an acceleration energy of 100 keV to 230 keV to a dose of 5×10¹⁴ ions/cm² to 1×10¹⁶ ions/cm².

9. The method of producing an SOI wafer according to claim 1, wherein immediately before the heat treatment in a chlorine-containing gas atmosphere, heat treatment is performed in a low oxygen atmosphere at an oxygen partial pressure ratio of less than 10%.

10. The method of producing an SOI wafer according to claim 2, wherein immediately before the heat treatment in a chlorine-containing gas atmosphere, heat treatment is performed in a low oxygen atmosphere at an oxygen partial pressure ratio of less than 10%.

11. The method of producing an SOI wafer according to any claim 3, wherein immediately before the heat treatment in a chlorine-containing gas atmosphere, heat treatment is performed in a low oxygen atmosphere at an oxygen partial pressure ratio of less than 10%.

12. The method of producing an SOI wafer according to claim 6, wherein immediately before the heat treatment in a chlorine-containing gas atmosphere, heat treatment is performed in a low oxygen atmosphere at an oxygen partial pressure ratio of less than 10%.

13. The method of producing an SOI wafer according to claim 7, wherein immediately before the heat treatment in a chlorine-containing gas atmosphere, heat treatment is performed in a low oxygen atmosphere at an oxygen partial pressure ratio of less than 10%.

14. The method of producing an SOI wafer according to claim 9, wherein immediately before the heat treatment in a chlorine-containing gas atmosphere, heat treatment is performed in a low oxygen atmosphere at an oxygen partial pressure ratio of less than 10%.
